(19) United States
(12) Patent Application Publication
(10) Pub. No.: US 2016/0249460 A1
(43) Pub. Date: Aug. 25, 2016

(54) Conductive Ink Composition for Offset or Reverse-Offset Printing

(71) Applicant: Hanwha Chemical Corporation, Seoul (KR)

(72) Inventors: Choong-Hoon Paik, Daejeon (KR); Won IL Son, Daejeon (KR); Seok Heon Oh, Daejeon (KR); Eui Duk Kim, Daejeon (KR)

(21) Appl. No.: 15/141,186

(22) Filed: Apr. 28, 2016

Related U.S. Application Data
(63) Continuation of application No. 13/976,572, filed on Sep. 17, 2013.

(30) Foreign Application Priority Data
Feb. 25, 2011 (KR) 10-2011-0017016
Feb. 23, 2012 (KR) 10-2012-0018482

(51) Int. Cl. H05K 3/12; C09D 11/033; H05K 1/09; C09D 11/102; C09D 11/103; B41F 16/00; C09D 11/52; C09D 11/037

(52) U.S. Cl. CPC H05K 3/1275; C09D 11/52; C09D 11/033; C09D 11/037; C09D 11/102; C09D 11/103; B41F 16/00; H05K 1/097

(57) ABSTRACT

There is provided a conductive ink composition for offset or reverse-offset printing, the conductive ink composition including a high boiling point solvent having a boiling point of 180 to 250° C. and a dispersion assistant solvent having a boiling point of 50 to 150° C., together with metal particles and tert-butyl alcohol as a main solvent.

### CROSS-REFERENCE TO RELATED APPLICATIONS

This application is a continuation of U.S. patent application Ser. No. 13/976,572, filed Sep. 17, 2013, entitled “Conductive Ink Composition for Offset or Reverse-Offset Printing”, which is the United States national phase under 35 U.S.C. §371 of International Application No. PCT/KR2012/001411 filed Feb. 24, 2012, which claims priority under 35 U.S.C. §119(a)-(d) to Korean Patent Application Nos. 10-2011-0017016, filed on Feb. 25, 2011, and 10-2012-0018482 filed on Feb. 23, 2012 in the Korean Intellectual Property Office, which are hereby incorporated by reference in their entirety.

### TECHNICAL FIELD

The following disclosure relates to a conductive ink composition for offset or reverse-offset printing.

### BACKGROUND ART

As electronic devices, information terminal devices, and the like have a smaller size and a smaller weight, electronic components used in the devices tend to be gradually smaller. Therefore, sizes of wiring patterns for being mounted in the electronic components are also gradually decreased, and widths of the wiring patterns or distances between the wiring patterns are gradually decreased.

An optical patterning method based on an exposing process and an etching process has been mainly used in order to form high-definition wiring patterns in the electronic component. However, the optical patterning method is not efficient since it unnecessarily wastes a lot of materials, requires a multistep process, and needs complicated processes such as using photoresist, developing liquids, or etching solution, and the like. Moreover, since a large-area mask needs to be used in the optical patterning method, it is difficult to apply a new design to a production line in the least amount of time. Therefore, in order to overcome disadvantages of the optical patterning method, there was developed a method of forming metal wirings through printing using an ink so that patterns are formed directly on the substrate without a mask.

An offset printer used in forming the metal wirings consists of an ink supply part, a columnar blanket and a printing plate. The ink patterns are transferred onto a substrate to be printed by the columnar blanket.

However, due to the trend of small sizes and high integration of products, degradation in transfer precision, such as enlargement in the line width of an ink pattern due to swelling of the blanket and the like, have emerged as serious problems. Hence, it is urgent to develop a conductive ink composition capable of forming ultra-fine metal patterns having a very small wiring width or a distance between wiring patterns.

### DISCLOSURE

### Technical Problem

An object of the present invention is to provide a conductive ink composition for offset or reverse-offset printing, capable of having excellent coatability onto a blanket, preventing swelling of the blanket, and having excellent transferability onto substrates to be printed including glass, and a conductive ink composition capable of having excellent dispersion stability, forming metal wirings having ultrafine patterns, and having excellent resistivity.

Hereinafter, an ink composition of the present invention will be described in detail. Here, unless indicated otherwise, the terms used in the specification including technical and scientific terms have the same meaning as those that are usually understood by those who skilled in the art to which the present invention pertains, and detailed description of the known functions and constitutions that may obscure the gist of the present invention will be omitted.

### Technical Solution

A conductive ink composition according to the present invention is characterized by being an ink composition for offset or reverse-offset printing, and contains a high boiling point solvent having a boiling point of 180 to 250° C. and a dispersion assistant solvent having a boiling point of 50 to 150° C., together with metal particles and tert-butyl alcohol, which is a main solvent.

In the conductive ink composition according to an embodiment of the present invention, the dispersion assistant solvent may have a solubility parameter of 9 to 11.

The conductive ink composition according to an embodiment of the present invention may contain tert-butyl alcohol as a main solvent, together with metal particles for giving conductivity thereto. The tert-butyl alcohol may be contained in a content of 40 to 65 wt % based on the total weight of the ink composition.

The tert-butyl alcohol constitutes a medium of the ink composition together with the high boiling point solvent and the dispersion assistant solvent, which will be described later, and thus, provides excellent coatability onto a material of the blanket and prevents swelling of the blanket.

The conductive ink composition of the present invention can have excellent coatability onto a polydimethylsiloxane (PDMS) material blanket and can prevent swelling of the PDMS material blanket.

In the case where other organic solvents having a similar solubility parameter (hereinafter, SP) to tert-butyl alcohol (SP: 10.6) is used as a main solvent, a conductive ink composition may not exhibit sufficient coatability and transferability onto the material of the blanket even though it contains the high boiling point solvent and the dispersion assistant solvent according to the present invention.

For example, in the case where solvents, such as iso-butanol (SP: 10.5), sec-butanol (SP: 10.8), ethoxy ethanol (SP: 10.5), isopropyl alcohol (SP: 11.5), and propylene glycol monomethyl ether acetate (SP: 9.2), are used as the main solvent, coatability of the conductive ink composition may be severely deteriorated. In the case where solvents having a low SP, such as toluene (SP: 8.9) and isopropyl acetate (SP: 8.4) are used as a main solvent, coatability is excellent but swelling of the blanket is worse.

In the conductive ink composition according to an embodiment of the present invention, the t-butyl alcohol may be contained in a content of 40 to 65 wt %, preferably 40 to 60 wt %, and more preferably 40 to 50 wt % based on the total weight of the ink composition. If the content of the t-butyl alcohol is below 40 wt %, coatability of the conductive ink composition may be at risk of deterioration. Further, if above 65 wt %, electric properties of conductive patterns to be printed may be at risk of deterioration.

As such, the conductive ink composition according to the present invention employs tent-butyl alcohol as a main solvent, and a high boiling point solvent having a boiling point of 180 to 250° C. and a dispersion assistant solvent having a boiling point of 50 to 150° C., as a sub solvent, and thus, can obtain excellent coatability and transferability, prevent swelling of a material of the blanket, and secure the waiting time of 30 seconds or longer after coating and before transferring. Further, the conductive ink composition according to the present invention is characterized by forming a uniform coating surface, preventing pinholes, improving dispersibility thereof, and preventing nozzles from being blocked.

For a substantial example, the high boiling point solvent may be at least one selected from terpineol, ethyl carbitol acetate, and butyl carbitol acetate.

The conductive ink composition according to an embodiment of the present invention may contain the high boiling point solvent in a content of 3 to 15 wt %, preferably 3 to 10 wt %, and more preferably 5 to 10 wt %.

The conductive ink composition according to an embodiment of the present invention contains the high boiling point solvent having a boiling point of 180 to 250° C. in a content of 3 to 15 wt % based on the total weight of the ink composition while employing tert-butyl alcohol as the main solvent, and thus, can secure the waiting time of 30 seconds or longer after coating and before transferring, can form a uniform coating surface by preventing agglomeration of the high boiling point solvent, and prevent pinholes.

In the conductive ink composition according to an embodiment of the present invention, the dispersion assistant solvent may have a boiling point of 50 to 150° C. and a solubility parameter of 9 to 11. For a substantial example, the dispersion assistant solvent may be at least one selected from acetone and propylene glycol monomethyl ether acetate.

The conductive ink composition according to an embodiment of the present invention may contain the dispersion assistant solvent in a content of 10 to 30 wt %, preferably 10 to 20 wt %, and more preferably 15 to 20 wt %.

As such, the conductive ink composition according to an embodiment of the present invention contains a dispersion assistant solvent having a boiling point of 50 to 1500 and a solubility parameter of preferably 9 to 11, in a content of 10 to 30 wt % based on the total weight of the ink composition while employing tert-butyl alcohol as a main solvent, and thus, can prevent swelling of PDMS, improve dispersibility thereof, prevent nozzles from being blocked by controlling volatile characteristics, and form a uniform coating surface.

The conductive ink composition according to an embodiment of the present invention employs the metal particles for giving conductivity thereto, and the metal particles may be copper particles, silver particles, or a mixture particles thereof, having an average particle size of 5 nm to 100 nm. The metal particles may include metal particles prepared by a liquid phase reduction method.

The conductive ink composition according to an embodiment of the present invention may contain the metal particles in a content of 20 to 40 wt %, preferably 20 to 35 wt %, and more preferably 25 to 35 wt %, based on the total weight of the ink composition.

The conductive ink composition according to an embodiment of the present invention may contain the metal particles in a content of 20 to 40 wt % based on the total weight of the ink composition. When the ink composition contains the metal particles of 20 to 40 wt %, a film thickness after coating and transferring is about 200 nm or thicker, so that excellent electric conductivity can be obtained after firing, and here, the film thickness is maintained to be 500 nm or thinner, so that very thin fine conductive patterns can be formed.

The conductive ink composition according to an embodiment of the present invention may further contain a binder and a dispersant.

In the conductive ink composition according to an embodiment of the present invention, the binder enhances binding strength between sintered ink patterns and a substrate on which the ink patterns are located. A binder resin that is commonly used in a field of ink composition easily dissolved in the above-described medium may be used for the binder. For example, the binder may be at least one material selected from phenol based resins and acrylic based resins. The acrylic based resins may include polyacrylic acid resin or polyacrylic ester resin, and the phenol based resins may include alkyl phenol based resins. The alkyl phenol based resins may include alkyl phenol-formaldehyde resin.

In the conductive ink composition according to an embodiment of the present invention, the binder may be contained in a content of 0.3 to 2 wt % and preferably 0.5 to 1.5 wt % based on the total weight of the ink composition, in order to obtain sufficient binding strength and prevent a deterioration in densification between the metal particles at the time of sintering.

In the conductive ink composition according to an embodiment of the present invention, the dispersant for improving dispersion stability may be a copolymer having an acid value of 50 mg KOH/g or higher and an amine value of 100 mg KOH/g or lower. For example, the dispersant may be a copolymer having an acid value of 50 mg KOH/g to 200 mg KOH/g and an amine value of 0 mg KOH/g to 100 mg KOH/g. For a substantial example, BYK102 (acid value: 101 mg KOH/g, amine value: 0 mg KOH/g), BYK110 (acid value: 53 mg KOH/g, amine value: 0 mg KOH/g), BYK145 (acid value: 76 mg KOH/g, amine value: 71 mg KOH/g), BYK180 (acid value: 94 mg KOH/g, amine value: 94 mg KOH/g), BYK995 (acid value: 53 mg KOH/g, amine value: 0 mg KOH/g), and BYK996 (acid value: 71 mg KOH/g, amine value: 0 mg KOH/g), which are commercial products from BYK Chemie Company, satisfying the above acid values and amine values, may be used as the dispersant.

The conductive ink composition according to an embodiment of the present invention may contain the dispersant in a content of 1 to 5 wt %, and preferably 1 to 3 wt % based on the total weight of the ink composition.

According to the conductive ink composition according to an embodiment of the present invention, conductive ink patterns may be printed as a target substrate by the PDMS material blanket. In addition, an electrode for a transistor, such as, a liquid crystal display thin film transistor (LCD TFT) or an organic field-effect transistor (OTFT), or a solar cell can be effectively formed by using the conductive ink composition according to an embodiment of the present invention. Here, the electrode for a solar cell may include a front electrode, a rear electrode, or a bus bar electrode for the solar cell.

### Advantageous Effects

The conductive ink composition according to the present invention can have excellent coatability onto a material of the blanket, particularly, a material of the PDMS blanket, and excellent stability onto the material of the blanket, thereby preventing swelling of the blanket. Further, conductive ink composition according to the present invention can obtain excellent transferability, secure the waiting time of 30 seconds or longer, form ultrafine metal patterns having a uniform coating surface and high electric conductivity, prevent pinholes, obtain excellent dispersion stability, and prevent nozzles from being blocked.

### DESCRIPTION OF DRAWINGS

FIG. 1 shows optical pictures of coating ((a) of FIG. 1) and transferring ((b) of FIG. 1) results using an ink composition according to Example 1 of the present invention;

FIG. 2 shows optical pictures of coating ((a) of FIG. 2) and transferring ((b) of FIG. 2) results using an ink composition according to Comparative example 1 of the present invention;

FIG. 3 shows optical pictures of coating ((a) of FIG. 3) and transferring ((b) of FIG. 3) results using an ink composition according to Comparative example 2 of the present invention;

FIG. 4 shows pictures obtained by observing a surface of a glass substrate ((a) of FIG. 4) and a surface of a blanket ((b) of FIG. 4) after transferring, in pattern transferring results using the ink composition according to Example 1 of the present invention;

FIG. 5 shows pictures obtained by observing a surface of a glass substrate ((a) of FIG. 5) and a surface of a blanket ((b) of FIG. 5) after transferring, in pattern transferring results using the ink composition according to Example 2 of the present invention;

FIG. 6 shows pictures obtained by observing a surface of a glass substrate ((a) of FIG. 6) and a surface of a blanket ((b) of FIG. 6) after transferring, in pattern transferring results using the ink composition according to Example 3 of the present invention; and

FIG. 7 shows pictures obtained by observing a surface of a glass substrate ((a) of FIG. 7) and a surface of a blanket ((b) of FIG. 7) after transferring, in pattern transferring results using the ink composition according to Comparative example 3.

### BEST MODE

### EXAMPLE 1

30 wt % of copper metal particles having an average particle size of 20 nm, 47 wt % of tert-butyl alcohol as a main solvent, 5 wt % of terpineol as a high boiling point solvent, 15 wt % of propylene glycol monomethyl ether acetate as a dispersion assistant solvent, 1 wt % of polyacrylic acid resin (Aldrich, Mw: 1800 or less) as a binder, and 2 wt % of BYK180 (copolymer having an acid value of 94 mg KOH/g and an amine value of 94 mg KOH/g) as a dispersant were mixed, and then the mixture was milled by using a boll mill for 2 hours. The thus obtained material was used as an ink for printing.

### EXAMPLE 2

30 wt % of copper metal particles having an average particle size of 20 nm, 42 wt % of tert-butyl alcohol as a main solvent, 10 wt % of terpineol as a high boiling point solvent, 15 wt % of propylene glycol monomethyl ether acetate as a dispersion assistant solvent, 1 wt % of polyacrylic acid resin (Aldrich, Mw: 1800 or less) as a binder, and 2 wt % of BYK180 (copolymer having an acid value of 94 mg KOH/g and an amine value of 94 mg KOH/g) as a dispersant were mixed, and then the mixture was milled by using a boll mill for 2 hours. The thus obtained material was used as an ink for printing.

### EXAMPLE 3

30 wt % of copper metal particles having an average particle size of 20 nm, 47 wt % of tert-butyl alcohol as a main solvent, 5 wt % of terpineol as a high boiling point solvent, 15wt % of acetone as a dispersion assistant solvent, 1 wt % of alkyl phenol-formaldehyde resin (Tackirol-101) as a binder, and 2 wt % of BYK110 (copolymer having an acid value of 53 mg KOH/g and an amine value of 0 mg KOH/g) as a dispersant were mixed, and then the mixture was milled by using a boll mill for 2 hours. The thus obtained material was used as an ink for printing.

### COMPARATIVE EXAMPLE 1

An ink for printing was prepared by the same method as Example 1 except that toluene was used as a main solvent.

### COMPARATIVE EXAMPLE 2

An ink for printing was prepared by the same method as Example 1 except that ethanol was used as a main solvent.

### COMPARATIVE EXAMPLE 3

30 wt % of copper metal particles having an average particle size of 20 nm, 52 wt % of tert-butyl alcohol as a main solvent, 15 wt % of propylene glycol monomethyl ether acetate as a dispersion assistant solvent, 1 wt % of polyacrylic acid resin (Aldrich, Mw: 1800 or less) as a binder, and 2 wt % of BYK110 (copolymer having an acid value of 53 mg KOH/g and an amine value of 0 mg KOH/g) as a dispersant were mixed without using a high boiling point solvent, and then the mixture was milled by using a boll mill for 2 hours. The thus obtained material was used as an ink for printing.

### COMPARATIVE EXAMPLE 4

30 wt % of copper metal particles having an average particle size of 20 nm, 62 wt % of tert-butyl alcohol as a main solvent, 5 wt % of terpineol as a high boiling point solvent, 1 wt % of polyacrylic acid resin (Aldrich, Mw: 1800 or less) as a binder, and 2 wt % of BYK110 (copolymer having an acid value of 53 mg KOH/g and an amine value of 0 mg KOH/g) as a dispersant were mixed without using a dispersant assistant solvent, and then the mixture was milled by using a boll mill for 2 hours. The thus obtained material was used as an ink for printing.

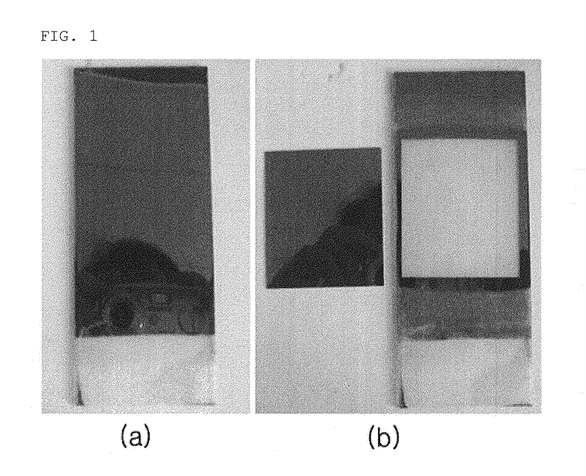

FIG. 1 shows observation results when the conductive ink composition according to Example 1 of the present invention was coated on a PDMS substrate, which was then transferred onto a glass substrate. As shown in FIG. 1, it can be seen that the conductive ink composition according to the present invention had excellent coatability onto the PDMS substrate and also had excellent transferability thereonto.

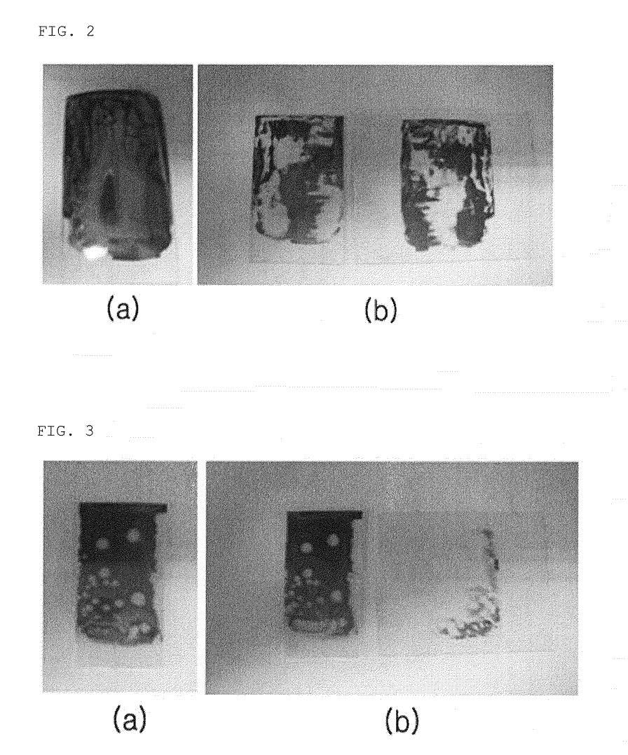

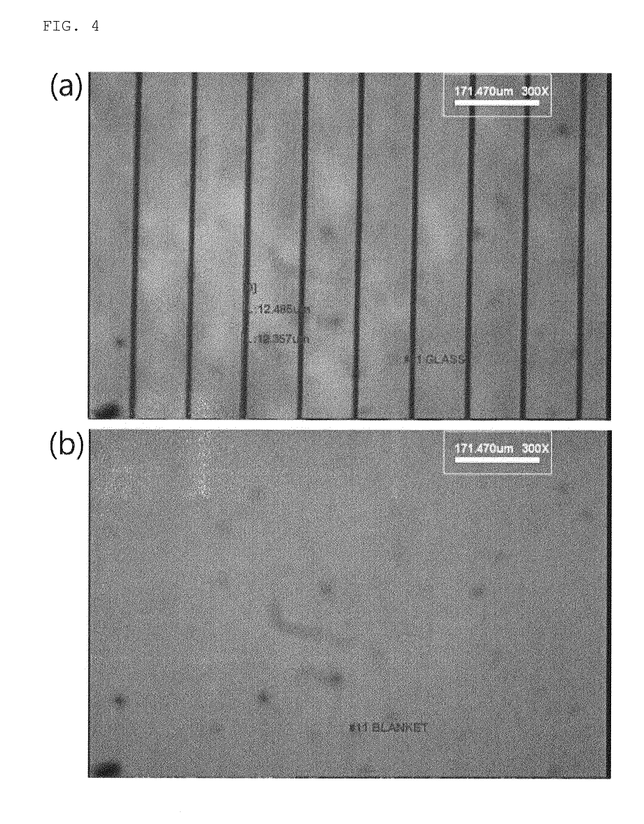

FIG. 2 and FIG. 3 show observation results when a conductive ink composition according to Comparative example 1 and a conductive ink composition according to Comparative example 2 each were coated on a PDMS substrate, which was then transferred onto a glass substrate. As shown in FIGS. 2 and 3, it can be confirmed that the ink composition not containing tert-butyl alcohol as a main solvent had very deteriorated coatability onto a PDMS substrate and very deteriorated transferability thereto even though it contains the high boiling point solvent and the dispersion assistant solvent of the present invention.

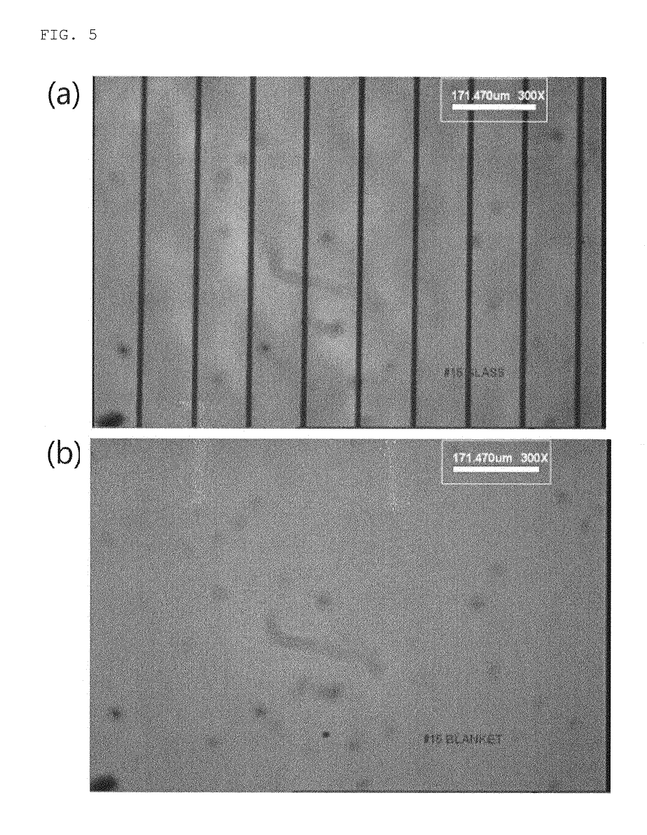

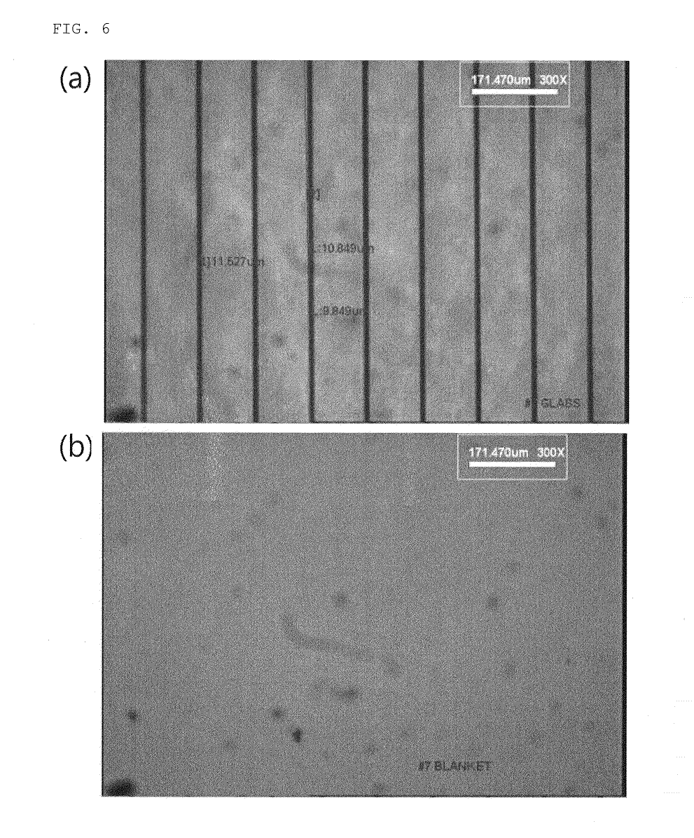

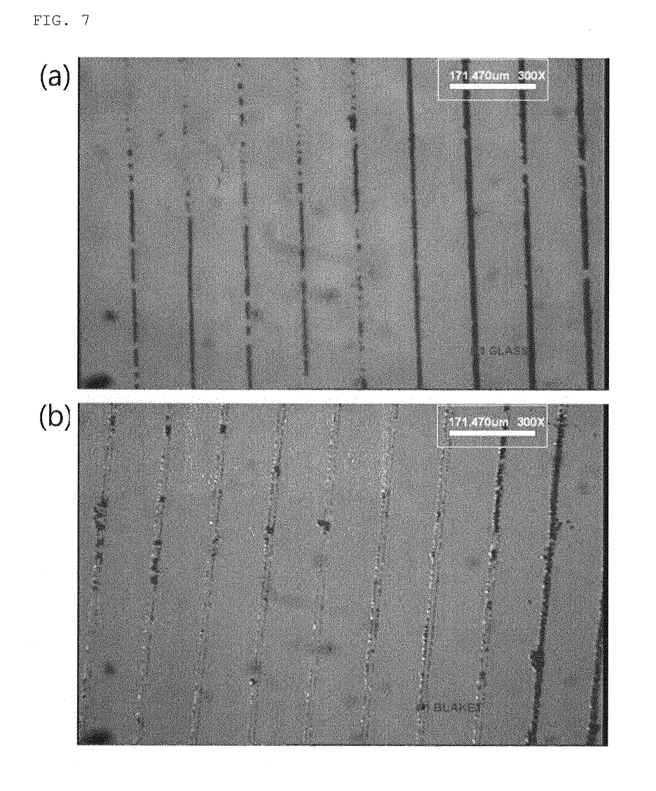

FIG. 4, FIG. 5 and FIG. 6 show observation results when a conductive ink composition according to Example 1, a conductive ink composition according to Example 2, and a conductive ink composition according to Example 3 each were reverse-offset printed on a glass substrate by using a PDMS material blanket. As shown in FIGS. 4 to 6, it can be seen that fine line patterns having a line width of about 10 μm were printed in a very uniform line width, and it can be confirmed that ink residues do not remain on a surface of the blanket after printing and the PDMS blanket had a smooth surface without swelling thereof.

FIG. 7 shows observation results when a conductive ink composition according to Comparative example 3 was reverse-offset printed on a glass substrate by using a PDMS material blanket. As shown in FIG. 7, it can be confirmed that, in the case of the conductive ink composition of Comparative example 3 where the high boiling point solvent was not used, since the waiting time after the time when it is coated on the blanket and before the time when it is transferred onto the glass substrate was very short, all the ink on the blanket was not transferred onto the glass substrate but remained on the surface of he blanket. Further, it can be confirmed that it is difficult to print patterns in a line type and the printed patterns had very irregular line widths.

Table 1 shows test results after offset-printing each of the conductive inks prepared from Examples 1 to 3 and Comparative examples 1 to 4 on a glass substrate by using a PDMS material blanket, and performing heat treatment on the glass substrate, on which the conductive ink patterns were transferred, at 350° C. in the nitrogen atmosphere for 5 minutes, in the similar manner to FIGS. 4 to 7.

TABLE 1

| | | | swelling | | binding | | |
|---|---|---|---|---|---|---|---|
| | Coat- | Transfer- | of | Dispersion | strength | waiting | |
| Ink | ability | ability | blanket | stability | to glass | time | resistivity |
| example 1 | good | good | weak | good | 100 | 70 | 4.7 |
| example 2 | good | good | weak | good | 100 | 100 | 4.2 |
| example 3 | good | good | weak | good | 100 | 50 | 4.5 |
| Comparative | good | failed | strong | good | 100 | 10 | — |
| example 1 | | | | | | | |
| Comparative | failed | failed | weak | failed | 100 | — | — |
| example 2 | | | | | | | |
| comparative | good | good | weak | good | 100 | 10 | 4.9 |
| example 3 | | | | | | | |
| comparative | good | good | weak | failed | 100 | 100 | 5.1 |
| example 4 | | | | | | | |

In Table 1, coatability in the case where uniform coating was performed without generation of pinholes was marked as “good” and coatability in the case where pinholes were generated was marked as “failed”, and transferability in the case where stable transferring was performed onto the glass substrate after the waiting time of 30 seconds, was marked as “good” and transferability in the case where stable transferring was not performed, such as, a pattern was disconnected or a line width of the pattern became thinner than the original line widths thereof was marked as “failed”.

In addition, dispersion stability was evaluated by leaving an ink for 2 weeks without stirring and then taking an upper portion of the ink, followed by analysis with a thermogravimetric analyzer. Dispersion stability in the case where the metal content in the ink was reduced to 1% or less was marked as “good”, and dispersion stability in the case where the metal content in the ink was reduced to 1% or more “failed”.

The binding strength to the glass was expressed by a ratio at which the metal come off from the tape by the Cross-Cut Test (ASTM D3359) after the ink transferred onto the glass substrate was fired at 350° C. A case in which the metal never come off from the tape is marked by “100” and a case in which all the metal come off from the tape is marked by “0”. The waiting time means the time for while stable transferring is possible after coating onto the blanket.

As described above, although the present invention is described by specific matters such as concrete components and the like, exemplary embodiments, and drawings, they are provided only for assisting in the entire understanding of the present invention. Therefore, the present invention is not limited to the exemplary embodiments. Various modifications and changes may be made by those skilled in the art to which the present invention pertains from this description. Therefore, the spirit of the present invention should not be limited to the above-described exemplary embodiments and the following claims as well as all modified equally or equivalently to the claims are intended to fall within the scopes and spirit of the invention.

1. A method of printing a conductive ink composition, comprising applying a conductive ink composition on a substrate using offset or reverse-offset printing, wherein the conductive ink composition comprises 3 to 15 wt % of a high boiling point solvent having a boiling point of 180 to 250° C. and 10 to 30 wt % of propylene glycol monomethyl ether acetate as a dispersion assistant solvent, together with 20 to 40 wt % of metal particles and 40 to 65 wt % of tert-butyl alcohol as a main solvent.

2. The method of printing a conductive ink composition of claim 1, wherein the offset or reverse-offset printing is performed by a polydimethylsiloxane (PDMS) material blanket.

3. The method of printing a conductive ink composition of claim 1, wherein the high boiling point solvent is at least one selected from terpineol, ethyl carbitol acetate, and butyl carbitol acetate.

4. The method of printing a conductive ink composition of claim 1, wherein the metal particles are copper particles, silver particles, or mixed particles thereof, having an average particle size of 5 nm to 100 nm.

5. The method of printing a conductive ink composition of claim 1, wherein the conductive ink composition further comprises a binder and a dispersant.

6. The method of printing a conductive ink composition of claim 5, wherein the binder is at least one selected from phenol based resin and acrylic based resin.

7. The method of printing a conductive ink composition of claim 5, wherein the dispersant is a copolymer having an acid value of 50 mg KOH/g or higher and an amine value of 100 mg KOH/g or lower.

8. The method of printing a conductive ink composition of claim 5, wherein the binder is contained in a content of 0.3 to 2 wt %; and the dispersant 1 to 5 wt %.
